(19) United States
(12) Patent Application Publication
(10) Pub. No.: US 2026/0065991 A1
(43) Pub. Date: Mar. 5, 2026

(54) SEMICONDUCTOR DEVICE AND OPERATING METHOD THEREOF, AND SYSTEM

(71) Applicant: Yangtze Memory Technologies Holding Co., Ltd., Wuhan (CN)

(72) Inventors: Yu ZHANG, Wuhan (CN); Feng XU, Wuhan (CN); Da LI, Wuhan (CN); Gang LIU, Wuhan (CN); Lei JIN, Wuhan (CN); Zongliang HUO, Wuhan (CN)

(21) Appl. No.: 19/264,450

(22) Filed: Jul. 9, 2025

(30) Foreign Application Priority Data
Aug. 28, 2024 (CN) 202411196642.3

(51) Int. Cl. G11C 16/04; G11C 7/16; G11C 16/10; G11C 16/26; H10B 43/10; H10B 43/27; H10B 43/35; H10B 43/40

(52) U.S. Cl. CPC G11C 16/0483; G11C 7/16; G11C 16/10; G11C 16/26; H10B 43/10; H10B 43/27; H10B 43/35; H10B 43/40

(57) ABSTRACT

Semiconductor devices, systems, and operating methods thereof are provided. An example semiconductor device includes: a stack structure including conductive layers and insulating layers stacked alternately along a first direction, a select gate layer located on the stack structure along the first direction, first select gate isolating structures penetrating through the select gate layer along the first direction, and second select gate isolating structures penetrating through the select gate layer along the first direction. A first select gate isolating structure divides the select gate layer into a plurality of select gate rows arranged along a second direction, and a second select gate isolating structure divides one or more select gate rows into a plurality of first select gates arranged along a third direction. The second direction intersects with the third direction, and the second direction and the third direction are both perpendicular to the first direction.

### CROSS-REFERENCE TO RELATED APPLICATIONS

This application claims priority to Chinese Patent Application No. 202411196642.3, filed on Aug. 28, 2024, which is hereby incorporated by reference in its entirety.

### TECHNICAL FIELD

The present disclosure relates to a field of semiconductor technology, and in particular, to a semiconductor device and an operating method thereof, and a system.

### BACKGROUND

In the classical von Neumann's computing architecture, a memory and a processor are separated, and data may be transferred between them through a data bus. When executing commands, the processor first reads data from the memory, processes the data, and then writes the updated data back to the memory. Frequent data migration brings huge power consumption and time overhead. In addition, due to the limited bandwidth of the memory, the processing speed of the processor is limited by the access speed of the memory, thereby limiting the improvement of the computing performance. With the rise of application fields such as big data and artificial intelligence, the processing requirements of massive amounts of data has made the bottleneck of von Neumann's computing architecture increasingly prominent.

### SUMMARY

In view of this, examples of the present disclosure may provide a semiconductor device and an operating method thereof, and a system.

In order to achieve the above object, a technical solution of an example of the present disclosure may be implemented as follows:
In a first aspect, an example of the present disclosure provides a semiconductor device, comprising:
a stack structure, comprising conductive layers and insulating layers stacked alternately along a first direction;
a select gate layer located on one of two opposite sides of the stack structure along the first direction;
a plurality of first select gate isolating structures extending along a third direction and penetrating through the select gate layer along the first direction; wherein the first select gate isolating structure divides the select gate layer into a plurality of select gate rows arranged along a second direction; the second direction intersects with the third direction, and the second direction and the third direction are both perpendicular to the first direction; and
a plurality of second select gate isolating structures extending along the second direction and penetrating through the select gate layer along the first direction; wherein the second select gate isolating structure divides the select gate row into a plurality of first select gates arranged along the third direction.

In an optional implementation, the semiconductor device further comprises:
a plurality of first channel structures extending along the first direction and penetrating through the stack structure;
a second channel structure extending along the first direction and penetrating through the first select gate; wherein a channel layer of one second channel structure is connected to a channel layer of one first channel structure; the first select gate isolating structure is located between two adjacent second channel structures in the second direction; the second select gate isolating structure is located between two adjacent second channel structures in the third direction; and a material of the select gate layer is different from a material of the conductive layer.

In an optional implementation, the semiconductor device further comprises:
a plurality of third channel structures extending along the first direction and penetrating through the stack structure and the select gate layer; wherein the first select gate isolating structure is located between two adjacent third channel structures in the second direction; the second select gate isolating structure is located between two adjacent third channel structures in the third direction; and a material of the select gate layer is the same as a material of the conductive layer.

In an optional implementation, the semiconductor device further comprises:
a gate line slit structure extending along the third direction and penetrating through the stack structure and the select gate layer along the first direction; wherein the gate line slit structure divides the stack structure and the select gate layer into a plurality of memory blocks arranged along the second direction; and the memory block comprising a plurality of select gate rows.

In an optional implementation, the semiconductor device further comprises:
a plurality of bit lines located on one side, away from the stack structure, of two opposite sides of the select gate layer along the first direction; wherein the bit line extends along the second direction and are arranged along the third direction; and one bit line is coupled to a plurality of the memory blocks arranged along the second direction; and
a plurality of lead-out structures located on one side, away from the stack structure, of two opposite sides of the select gate layer along the first direction; wherein one end of two opposite ends of one lead-out structure along the first direction is connected to one first select gate; and at least one bit line exists between two adjacent lead-out structures in the third direction.

In an optional implementation, the semiconductor device further comprises:
a conductive wire connected to the other end of the two opposite ends of the lead-out structures along the first direction; wherein one conductive wire is connected to one lead-out structure; and the conductive wires extend along the second direction and are arranged along the third direction.

In an optional implementation, the semiconductor device further comprises a peripheral circuit coupled to the plurality of memory blocks; wherein the peripheral circuit is configured to:
apply corresponding input voltages to a plurality of first select gates in the memory block simultaneously based on input data during an operation phase with the semiconductor device.

In an optional implementation, the semiconductor device comprises a plurality of memory banks; wherein the memory bank comprises a plurality of memory blocks arranged along the second direction; one bit line is coupled to a plurality of memory blocks arranged along the second direction in the memory bank; and the peripheral circuit is further configured to:
apply corresponding input voltages to a plurality of first select gates in at least two memory blocks in the memory banks simultaneously based on input data during the operation phase with the semiconductor device.

In an optional implementation, the peripheral circuit is further configured to:
perform a programming operation on memory cells in the memory block based on a weight matrix to write weights in the weight matrix to the memory cells, before the operation phase is performed with the semiconductor device.

In an optional implementation, the peripheral circuit is further configured to:
apply a same voltage to a plurality of first select gates in a same select gate row in the memory block during a programming phase on the memory cells in the memory block.

In an optional implementation, the peripheral circuit is further configured to:
apply a read voltage to a target word line coupled to the memory block during the operation phase with the semiconductor device;
apply a first turn-on voltage to a non-target word line coupled to the memory block; and
obtain an operation result of the input data and the weights stored in the memory cells coupled to the target word line based on currents on a plurality of bit lines coupled to the memory block.

In an optional implementation, each memory block comprises a plurality of memory cell strings, one bit line is coupled to the plurality of memory cell strings in the memory block; a current on the one bit line coupled to the memory block is a sum of output currents of the plurality of memory cell strings coupled to the bit line in the memory block; in a circumstance that the input voltage applied to the first select gate makes a select transistor comprising the first select gate in a turn-on state, and a threshold voltage of a memory cell coupled to the target word line in the memory cell string is less than the read voltage, an output current of the memory cell string is greater than or equal to a preset current.

In an optional implementation, the memory block further comprises a second select gate; wherein the second select gate is located on the other side of the two opposite sides of the stack structure along the first direction; and the peripheral circuit is further configured to:
apply a second turn-on voltage to the second select gate in the memory block during the operation phase with the semiconductor device.

In an optional implementation, the first select gate is one of a top select gate and a bottom select gate; and the second select gate is the other one of the top select gate and the bottom select gate.

In an optional implementation, the peripheral circuit comprises:
an analog-to-digital conversion circuit, a digital-to-analog conversion circuit, a voltage generator, a column decoder, and a control logic; wherein the analog-to-digital conversion circuit is coupled to the column decoder and the control logic; and the digital-to-analog conversion circuit is coupled to the voltage generator and the control logic.

In an optional implementation, the plurality of memory blocks and the peripheral circuit are stacked along the first direction.

In an optional implementation, the semiconductor device comprises a three-dimensional NAND type memory.

In a second aspect, an example of the present disclosure provides a system, comprising:
at least one semiconductor device according to any one of the above examples; and
a controller, coupled to the at least one semiconductor device and configured to transmit input data to the semiconductor device and receive an operation result of the semiconductor device.

In a third aspect, an example of the present disclosure provides an operating method of a semiconductor device, wherein the semiconductor device comprises a plurality of memory blocks; the memory block comprises a plurality of select gate rows arranged along a second direction; the select gate row comprises a plurality of first select gates arranged along a third direction; the second direction intersects with the third direction; and the operating method comprises:
applying corresponding input voltages to a plurality of first select gates in the memory block simultaneously based on input data during an operation phase with the semiconductor device.

In an optional implementation, the semiconductor device comprises a plurality of memory banks; wherein the memory bank comprises a plurality of memory blocks arranged along the second direction; and the operating method further comprises:
applying corresponding input voltages to a plurality of first select gates in at least two memory blocks in the memory banks simultaneously based on input data during the operation phase with the semiconductor device.

In an optional implementation, the operating method further comprises:
performing a programming operation on memory cells in the memory block based on a weight matrix to write weights in the weight matrix to the memory cells before the operation phase is performed with the semiconductor device.

In an optional implementation, the operating method further comprises:
applying a same voltage to a plurality of first select gates in a same select gate row in the memory block during a programming phase on the memory cells in the memory block.

In an optional implementation, the operating method further comprises:
applying a read voltage to a target word line coupled to the memory block during the operation phase with the semiconductor device;
applying a first turn-on voltage to a non-target word line coupled to the memory block; and
obtaining an operation result of the input data and the weights stored in the memory cells coupled to the target word line based on currents on a plurality of bit lines coupled to the memory block.

In an optional implementation, each memory block comprises a plurality of memory cell strings, one bit line is coupled to the plurality of memory cell strings in the memory block; a current on the one bit line coupled to the memory block is a sum of output currents of a plurality of memory cell strings coupled to the bit line in the memory block; in a circumstance that the input voltage applied to the first select gate makes a select transistor comprising the first select gate in a turn-on state, and a threshold voltage of a memory cell coupled to the target word line in the memory cell string is less than the read voltage, an output current of the memory cell string is greater than or equal to a preset current.

In an optional implementation, the memory block further comprises a second select gate; and the operating method further comprises:
applying a second turn-on voltage to the second select gate in the memory block during the operation phase with the semiconductor device.

In the technical solution provided by the present disclosure, the semiconductor device comprises a select gate layer located on one of two opposite sides of the stack structure along the first direction, the select gate layer may be divided into a plurality of first select gates by a first select gate isolating structure extending along the third direction and a second select gate isolating structure extending along the second direction, and during the operation phase with the semiconductor device, the peripheral circuit may be configured to apply corresponding input voltages to the plurality of first select gates in the memory block based on the input data. As a result, the input parallelism can be improved, which can significantly improve the flexibility and efficiency of the operation, and facilitate the implementation of more complex operation schemes with the semiconductor device.

### BRIEF DESCRIPTION OF THE DRAWINGS

FIG. 1 is a first schematic composition diagram of a system according to an example of the present disclosure.

FIG. 2 is a second schematic composition diagram of a system according to an example of the present disclosure.

FIG. 3 is a schematic diagram of an example memory card having a memory system according to an example of the present disclosure.

FIG. 4 is a schematic diagram of an example solid state disk having a memory system according to an example of the present disclosure.

FIG. 5 is a first schematic diagram of a semiconductor device comprising a peripheral circuit and a memory array according to an example of the present disclosure.

FIG. 6 is a second schematic diagram of a semiconductor device comprising a peripheral circuit and a memory array according to an example of the present disclosure.

FIG. 7 is a schematic diagram of inputting an input voltage into a memory block by a word line according to an example of the present disclosure.

FIG. 8 is a schematic composition diagram of a memory array according to an example of the present disclosure.

FIG. 9 is a first top view of a semiconductor device according to an example of the present disclosure.

FIG. 10 is a perspective view of a partial structure in region A of FIG. 9.

FIG. 11 is a top view of a partial structure in region A of FIG. 9.

FIG. 12 is a cross-sectional view of FIG. 11 along line BB′.

FIG. 13 is a cross-sectional view of a semiconductor device according to another example of the present disclosure.

FIG. 14 is a second top view of a semiconductor device according to an example of the present disclosure.

FIG. 15 is a schematic perspective view of a partial structure of a semiconductor device according to an example of the present disclosure.

FIG. 16 is a third top view of a semiconductor device according to an example of the present disclosure.

FIG. 17 is a schematic diagram of a threshold voltage distribution of a memory cell according to an example of the present disclosure.

FIG. 18 is a schematic diagram of an arrangement of first select gates in a memory block according to an example of the present disclosure.

FIG. 19 is an equivalent circuit diagram of a plurality of memory cell strings comprising one select gate row according to an example of the present disclosure.

FIG. 20 is an equivalent circuit diagram of a plurality of memory cell strings coupled to one bit line according to an example of the present disclosure.

FIG. 21 is a schematic flowchart of an operating method of a semiconductor device according to an example of the present disclosure.

### DETAILED DESCRIPTION

Example aspects disclosed in the present disclosure will be described in more detail below with reference to the accompanying drawings. Although example aspects of the present disclosure are shown in the accompanying drawings, it should be understood that the present disclosure may be implemented in various forms and should not be limited to the aspects set forth herein. Rather, these aspects are provided so that the present disclosure can be more thoroughly understood and the scope disclosed in the present disclosure can be fully conveyed to those skilled in the art.

In the following description, numerous details are given in order to provide a more thorough understanding of the present disclosure. However, it will be apparent to one skilled in the art that, the present disclosure may be practiced without one or more of these details. In other examples, in order to avoid confusion with the present disclosure, some technical features known in the art are not described; that is, not all features of the actual examples are described here, and well-known functions and structures are not described in detail.

In the drawings, like reference numerals refer to like elements throughout.

It should be understood that spatial relation terms such as “beneath,” “below,” “lower,” “under”, “above,” “upper,” etc., may be used herein for ease of description to describe the relationship between one element or feature and other elements or features shown in the figures. It should be appreciated that, in addition to the orientations shown in the figures, the spatial-relation terms intent to also comprise different orientations of the devices in use and operation. For example, if the devices in the figures are flipped, then described as “below” or “under” or “beneath” other elements or features will be oriented “on” other elements or features. Thus, the example terms “below” and “beneath” may comprise both upper and lower orientations. The devices may be additionally oriented (rotated 90 degrees or other orientations) and the spatial description terminology used herein is interpreted accordingly.

A term used herein is for the purpose of describing a particular example only and is not to be considered as limitation of the present disclosure. As used herein, “a”, “an” and “said/the” in the singular form are intended to comprise the plural forms as well, unless the context indicated clearly otherwise. It should also be understood that the terms at least one of “consists of” or “comprising”, when used in this description, identify the presence of at least one of stated features, integers, steps, operations, elements or components, but do not exclude the presence and addition of at least one of one or more other features, integers, steps, operations, elements, components or groups. As used herein, the term “at least one of” comprises any and all combinations of the related listed items.

In the classic von Neumann's computing architecture, a memory for storing data is separate from a processor for data processing, and the data may be transferred between the memory and the processor through a data bus. When executing the data processing command, the processor first needs to read the data from the memory, and then writes the updated data back into the memory, which requires data to be frequently transferred between the memory and the processor and leads to huge power consumption and time overhead. In addition, due to the limited bandwidth of the memory, the processing speed of the processor is limited by the access speed of the memory, so that the computing performance may be limited. With the rise of application fields such as big data and artificial intelligence, the processing requirements of massive data has made the bottleneck of von Neumann's computing architecture increasingly prominent.

In order to solve the bottleneck of the classic von Neumann's computing architecture, the compute-in-memory chip architecture emerges, and the basic idea is to directly use the memory for logic computation, thereby reducing the overhead incurred by frequent transmission of data between the memory and the processor, and improving the computing performance while reducing power consumption.

The compute-in-memory chip has both storage and computing capabilities relying on its own physical characteristics. The storage capability refers to the capability of implementing numerical storage by changing a conductance value of a memory cell, according to the physical characteristics of the memory cells of different types of memories, and the computing capability refers to the capability of implementing a multiply accumulate (MAC) operation according to Ohm's law and Kirchhoff's law, by constructing an array comprising memory cells.

In some examples, for the compute-in-memory chip, by changing the conductance value of the memory cell, a weight matrix may be stored in the memory array according to a certain mapping rule. In an example, the conductance value of each memory cell may represent one weight in the weight matrix. After the weight matrix is written into the memory array, an element of the input vector may be mapped to a voltage value at an input end of the memory array. Taking a plurality of elements of the input vector being mapped to a plurality of rows of input voltages as an example, based on Ohm's law, current output by each memory cell in the memory array represents a result of multiplication operation on one element of the input vector and one weight, based on Kirchhoff's law, current output by a column of memory cells may be accumulated to obtain a computation result after the plurality of multiplication results are accumulated, the computation result output by a column of memory cells may correspond to one element of the output vector, and then the computation result of the weight matrix and the input vector may be output through the memory array comprising a plurality of columns of memory cells. Therefore, the memory array in the compute-in-memory chip not only stores the weight matrix to achieve the storage function, but also achieves the computing function.

In some examples, the compute-in-memory chip may comprise at least one of the memories such as a Static Random Access Memory (SRAM), a Dynamic Random Access Memory (DRAM), a Phase-Change Memory (PCM), a NAND Flash Memory, or the like. The NAND flash memory is a non-volatile memory, which has a large memory capacity, especially a three-dimensional NAND type memory with a three-dimensional structure, which has a high memory density and has the potential to be developed into a compute-in-memory chip. The details of the three-dimensional NAND type memory will be described below.

In some examples, a system comprising a three-dimensional NAND type memory comprises a semiconductor device and a controller coupled to the semiconductor device. The controller is configured to transmit an input vector or an input matrix to the semiconductor device and receive an operation result of the semiconductor device.

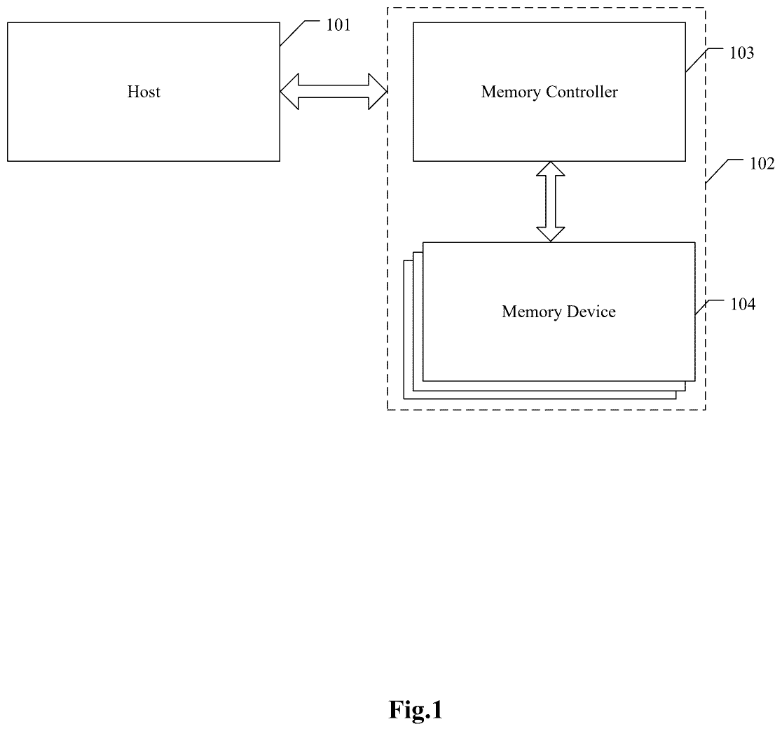

In some examples, the system in the above example may be a memory system 102 shown in FIG. 1, the memory system 102 comprises a memory controller 103 and a memory device 104 coupled to the memory controller 103, the controller in the above example may be the memory controller 103, and the semiconductor device may be the memory device 104.

According to some implementations, as shown in FIG. 1, the memory controller 103 is coupled to the memory device 104 and a host 101, and is configured to control operations of the memory device 104, such as operations of reading, erasing, programming, and computing. The memory controller 103 may manage data stored in the memory device 104 and communicate with the host 101.

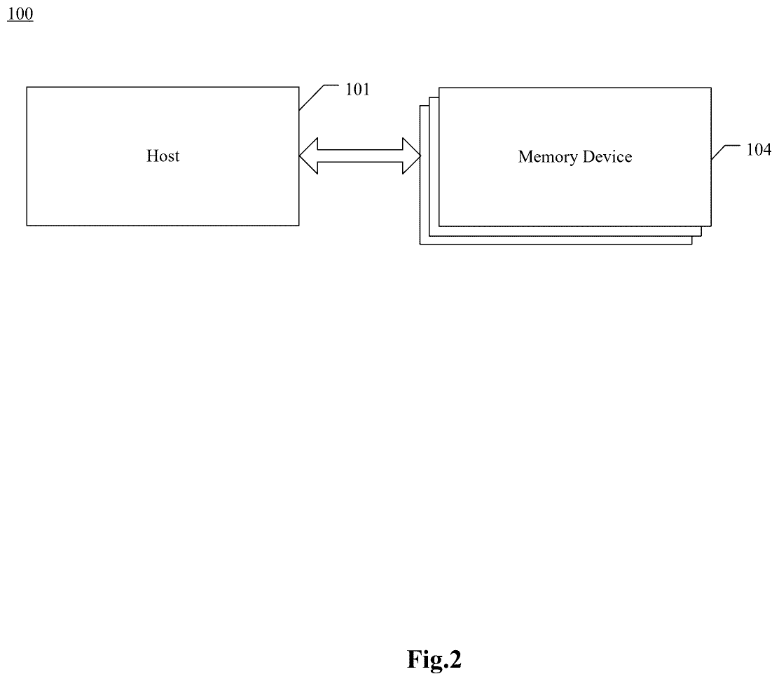

In some examples, the system in the above example may be a system 100 shown in FIG. 2, the system 100 comprises a host 101, and a memory device 104 that may communicate directly with the host 101, and the controller in the above example may be a central processing unit (CPU) in the host 101, and the semiconductor device in the above example may be the memory device 104.

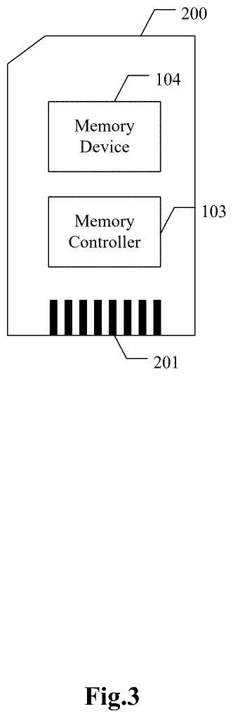

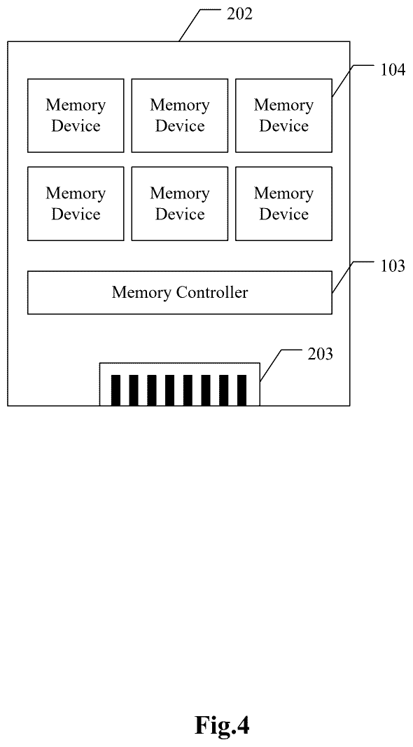

In an example as shown in FIG. 3, a system may be integrated into the memory card 200, a semiconductor device in the system may be the memory device 104 in the memory card 200, and a controller in the system may be the memory controller 103 in the memory card 200. The memory card 200 may be at least one of a compact flash memory card, a smart media card (SMC), a memory stick (MS), a multi-media card (MMC), such as an RS-MMC, an MMCmicro, an eMMC, or the like, a secure digital card, such as a Mini SD card, a Micro SD card, an SDHC card, or the like, and a universal flash memory card. The memory card 200 may also comprise a memory card connector 201 that couples the memory card 200 with a host. In an example as shown in FIG. 4, a system may be integrated into a solid state disk (SSD) 202, the semiconductor device in the system may be the memory device 104 in the solid state disk 202, and the controller in the system may be the memory controller 103 in the solid state disk 202. The solid state disk 202 may further comprise a solid state disk connector 203 that couples the solid state disk 202 with a host-side device. In some implementations, at least one of the storage capacity or operating speed of the solid state disk 202 is greater than at least one of the storage capacity or the operating speed of the memory card 200.

In some examples, the system may be integrated in the terminal device, the controller may be a CPU of the terminal device, and the terminal device may comprise, but not limited to, any terminal device such as a mobile phone, a smart television, a smart speaker, a wearable device, a tablet computer, a desktop computer, a computer integrated machine, a handheld computer, a notebook computer, a server, an ultra-mobile personal computer (UMPC), a netbook, a personal digital assistant (PDA), a laptop, a mobile computer, an augmented reality (AR) device, a virtual reality (VR) device, an artificial intelligence (AI) device, or a portable terminal device.

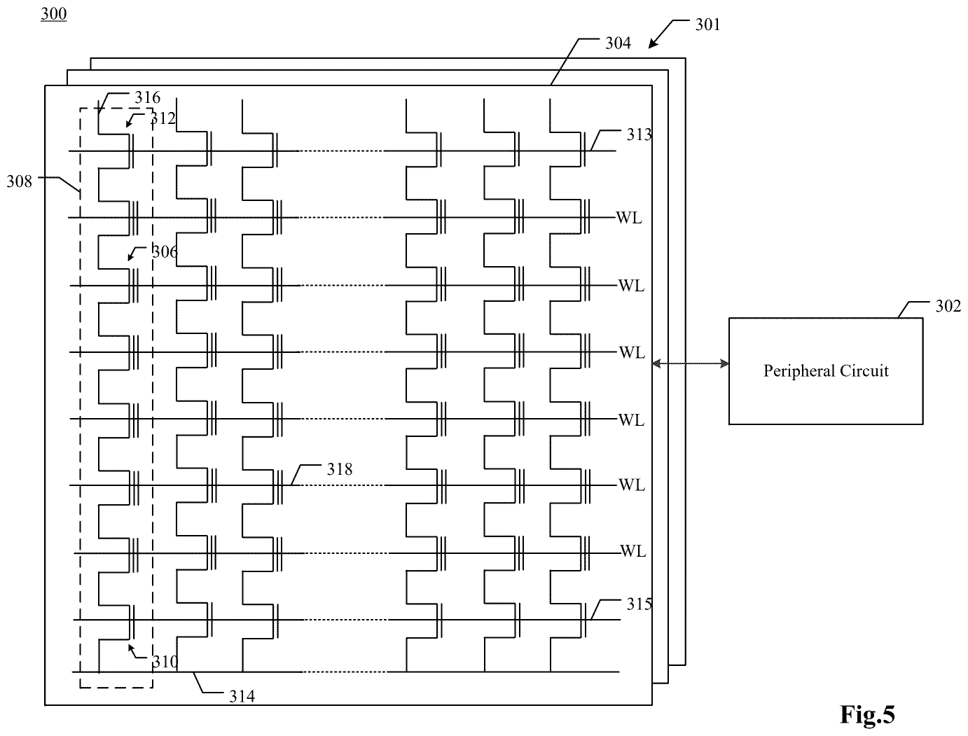

FIG. 5 is a first schematic composition diagram of a semiconductor device according to an example of the present disclosure. The semiconductor device 300 may comprise a memory array 301 and a peripheral circuit 302 coupled to the memory array 301. The memory array 301 is a three-dimensional NAND type memory array, wherein the memory cell 306 is a NAND memory cell, the memory cell 306 is provided in the form of an array of memory cell strings 308, with each memory cell string 308 extending vertically. In some implementations, each memory cell string 308 comprises a plurality of memory cells 306 coupled in series and stacked vertically. Each memory cell 306 may hold a continuous analog value, e.g., voltage or charge, depending on the number of electrons captured by the memory cell 306. Each memory cell 306 may be a memory cell of charge trapping type comprising a charge trapping transistor.

In some implementations, each memory cell 306 is a single level cell (SLC) having two possible memory states and thus may store one bit of data. For example, a first memory state “0” may correspond to a first voltage range and a second memory state “1” may correspond to a second voltage range. In some implementations, each memory cell 306 is a multi-level cell capable of storing more than a single bit of data with four or more memory states, e.g., a multi-level cell (MLC) storing two bits per cell, a triple level cell (TLC) storing three bits per cell, or a quad-level cell (QLC) storing four bits per cell.

As shown in FIG. 5, each memory cell string 308 may comprise a bottom select transistor 310 at its source end and atop select transistor 312 at its drain end. The bottom select transistor 310 and the top select transistor 312 may be configured to activate a selected memory cell string 308 during read and programming operations. For example, during a programming operation, the top select transistor 312 in a selected memory cell string 308 may be turned on, and the top select transistor 310 in an unselected memory cell string 308 may be turned off, so that only the selected memory cell string 308 may be coupled to the bit line (BL) 316, that is, the selected memory cell string 308 is activated.

In some implementations, the sources of the memory cell strings 308 in the same memory block 304 may be coupled through a common source line (CSL) 314. In other words, all the memory cell strings 308 in the same memory block 304 have a common source (Array Common Source, ACS). According to some implementations, the top select transistor 312 of each memory cell string 308 is coupled to a respective bit line 316, from which data may be read or written via an output bus (not shown). In some implementations, each memory cell string 308 is configured to be selected or deselected by at least one of: applying a select voltage (e.g., a voltage higher than a threshold voltage of the top select transistor 312) or a deselect voltage (e.g., OV) to the respective top select transistor 312 through one or more top select lines (TSL) 313 or applying a select voltage (e.g., a voltage higher than a threshold voltage of the bottom select transistor 310) or a deselect voltage (e.g., OV) to the respective bottom select transistor 310 through one or more bottom select lines (BSL) 315.

As shown in FIG. 5, the memory cell string 308 may be organized into a plurality of memory blocks 304, each of which may have a common source line 314. In some implementations, each memory block 304 is a basic data unit for an erase operation, i.e., all memory cells 306 in the same memory block 304 may be erased simultaneously. To erase the memory cells 306 in the selected memory block, a common source line 314 coupled to the selected memory block and unselected memory block in the same plane as the selected memory block may be biased with an erase voltage. It should be understood that in some examples, the erase operation may be performed at a half-memory block level, at a quarter-memory block level, or at a level with any suitable number of memory blocks or any suitable fraction of a memory block. Memory cells 306 of adjacent memory cell strings 308 may be coupled by word lines 318, which may select which row of memory cells 306 is affected by a read or programming operation.

In some examples, the peripheral circuit 302 may comprise any suitable analog, digital, and mixed-signal circuit for implementing an operation on the memory array 301 by applying at least one of a voltage signal or a current signal to and sensing at least one of a voltage signal or a current signal from each of the target memory cells 306 through the bit line 316, the word line 318, the common source line 314, the bottom select line 315, and the top select line 313. Peripheral circuit 302 may comprise various types of peripheral circuit formed with metal-oxide-semiconductor technology.

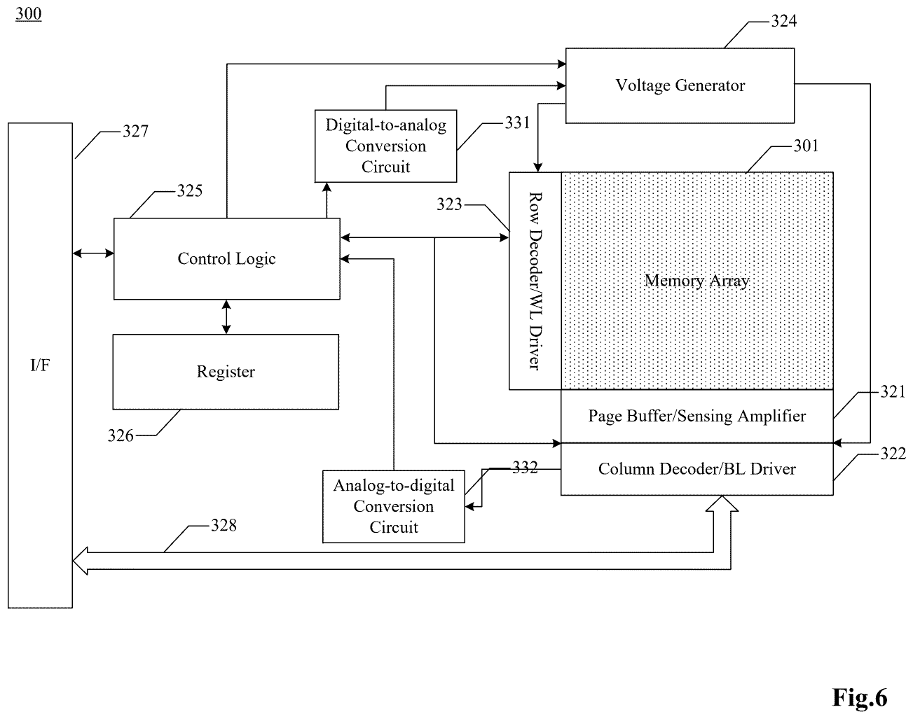

FIG. 6 is a second schematic composition diagram of a semiconductor device according to an example of the present disclosure. As shown in FIG. 6, the peripheral circuit may comprise a page buffer/sensing amplifier 321, a column decoder/bit line driver 322, a row decoder/word line driver 323, a voltage generator 324, control logic 325, a register 326, a flash memory interface 327, and a data bus 328.

The page buffer/sensing amplifier 321 may be configured to read data from and program (write) data to the memory array 301 according to a control signal from the control logic 325. In an example, the page buffer/sensing amplifier 321 may store a page of programming data (write data) to be programmed to the memory array 301. In another example, the page buffer/sensing amplifier 321 may perform a programming verification operation to ensure that data has been properly programmed into memory cells coupled to the selected word line. In yet another example, the page buffer/sensing amplifier 321 may also sense a low power signal from the bit line representing a data bit stored in the memory cell, and amplify the small voltage swing to an identifiable logic level in a read operation. Column decoder/bit line driver 322 may be configured to be controlled by the control logic 325 and select one or more memory cell strings by applying a bit line voltage generated from the voltage generator 324.

The row decoder/word line driver 323 may be configured to be controlled by the control logic 325 and select/deselect a memory block of the memory array 301 and select/deselect a word line of the memory block. The row decoder/word line driver 323 may also be configured to drive the word line with a word line voltage generated from the voltage generator 324. In some implementations, the row decoder/word line driver 323 may also select/deselect and drive the bottom select line and the top select line. As described in detail below, the row decoder/word line driver 323 is configured to perform a programming operation on memory cells coupled to the selected word line(s). The voltage generator 324 may be configured to be controlled by the control logic 325 and generate a word line voltage (e.g., a read voltage, a programming voltage, a pass voltage, a local voltage, a verification voltage, etc.), a bit line voltage, and a source line voltage to be supplied to the memory array 301.

The control logic 325 may be coupled to each circuit described above. and configured to control the operation of each circuit. The registers 326 may be coupled to the control logic 325 and comprise a status register, a command register, and an address register for storing status information, command operation code (OP code), and command addresses for controlling operations of each peripheral circuit. the flash interface 327 may be coupled to the control logic 325 and act as a control buffer to buffer a control command received from a host-side device (not shown) and relay it to the control logic 325 and buffer status information received from the control logic 325 and relay it to the memory controller. the flash interface 327 may also be coupled to the column decoder/bit line driver 322 via the data bus 328 and act as a data I/O interface and a data buffer to buffer data and relay it to the memory array 301 or relay or buffer data from the memory array 301.

In some examples, with reference to FIG. 6, when the semiconductor device comprising the three-dimensional NAND type memory is used as a compute-in-memory chip, in addition to the above circuits, the peripheral circuit may further comprise a digital-to-analog conversion circuit 331 and an analog-to-digital conversion circuit 332. The digital-to-analog conversion circuit 331 is connected to the control logic 325 and the voltage generator 324, and the analog-to-digital conversion circuit 332 is connected to the control logic 325 and the column decoder/BL driver 322. During the operation phase with the three-dimensional NAND type memory, the control logic 325 may receive the input data transmitted by the controller, the digital-to-analog conversion circuit 331 may convert the input data into a voltage signal, the voltage generator 324 may generate a corresponding input voltage based on the voltage signal; the analog operation result obtained after the operation may be transmitted to the analog-to-digital conversion circuit 332, and the analog-to-digital conversion circuit 332 may convert the analog operation result into a digital operation result.

In some examples, the compute-in-memory chip needs to implement the operation of input data and a weight matrix, the input data may be an input vector or an input matrix comprising a plurality of elements, the weight matrix comprised a plurality of weights, and a multiply-accumulate operation needs to be performed on each element of the input data and the plurality of weights in the weight matrix to obtain a corresponding element of the output data.

To implement the above operation, the memory array in the semiconductor device may be configured to store a weight matrix, as an example, the weights in the weight matrix may be written into the memory array according to a certain mapping rule, and each memory cell in the memory array may be configured to store one weight. During the inference phase, the semiconductor device may receive input data from the controller, the input data may be an input vector or an input matrix comprising a plurality of elements, and each element of the input data may be converted into an input voltage by the digital-to-analog conversion circuit, and the input voltage may be input to the memory array by a bit line or a word line.

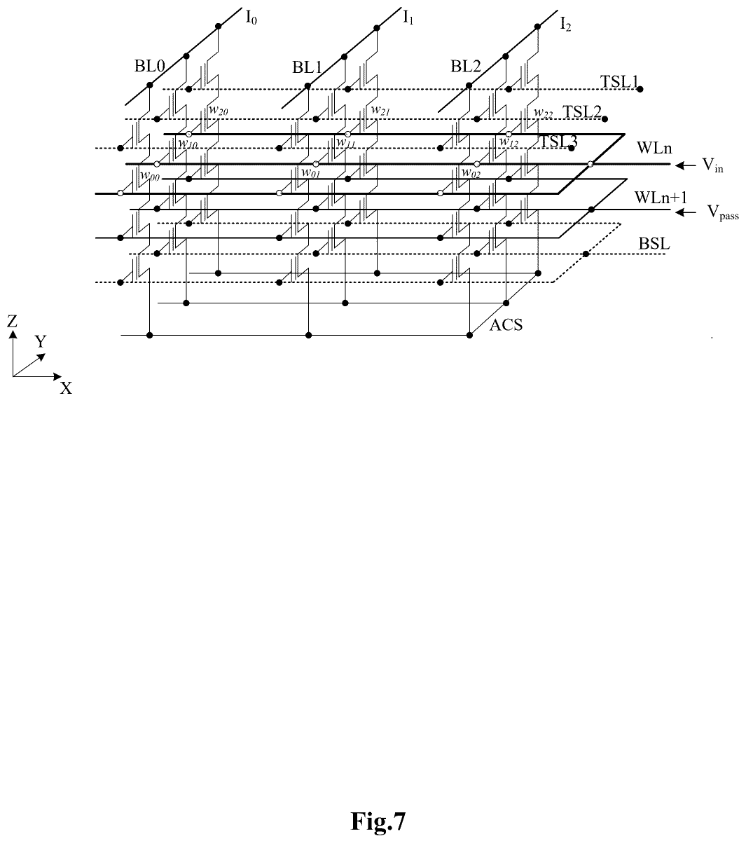

In some examples, FIG. 7 is a schematic diagram of inputting an input voltage into a memory block by a word line. As shown in FIG. 7, the memory cells coupled to a target word line WLn may be configured to store a weight matrix, as an example, the memory state corresponding to a threshold voltage of the memory cell may correspond to one weight. An input voltage Vᵢₙ may be applied to the target word line WLn, and a turn-on voltage Vₚₐₛₛ may be applied to a non-target word line coupled to the same memory block, so that the memory cells coupled to the non-target word line may be all in the turn-on state, in this case, whether each memory cell string generates a significant current is only related to whether the threshold voltage of the memory cell coupled to the target word line WLn is greater than the input voltage Vᵢₙ. When the input voltage Vᵢₙ is greater than the threshold voltage of the memory cell, the memory cell string to which the memory cell belongs is turned on and generates a significant current, when the input voltage Vᵢₙ is less than the threshold voltage of the memory cell, the memory cell string to which the memory cell belongs is turned off, and no significant current is generated. In this case, current on each bit line may be respectively detected at an end of the bit line that coupled to the sensing circuit, and taking the bit line BL0 as an example, the current I₀ thereon corresponds to a result of multiplying the input data corresponding to the input voltage Vᵢₙ and the weights w₀₀, w₁₀, w₂₀ and then accumulating the products.

In the above example, an operation of only one element of the input data and the weight matrix can be performed at a time, resulting a relatively low flexibility, and when the input data is an input vector or an input matrix comprising a plurality of elements, input voltages corresponding to the plurality of elements needs to be sequentially input by the target word line WLn, resulting in a long operation period and a low operation efficiency. Therefore, it is necessary to further optimize the operation scheme of the semiconductor device comprising the three-dimensional NAND type memory. In this regard, the present disclosure provides the following implementations.

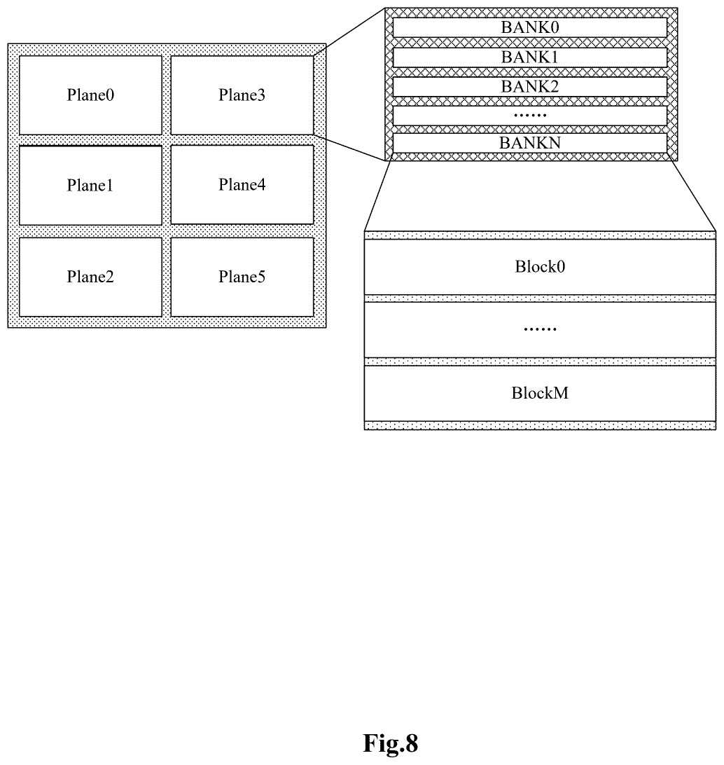

The present disclosure provides a semiconductor device comprising a memory array. FIG. 8 is a schematic composition diagram of a memory array according to an example of the present disclosure. As shown in FIG. 8, the memory array may comprise a plurality of memory planes, each memory plane comprises a plurality of memory banks, and each memory bank comprises a plurality of memory blocks.

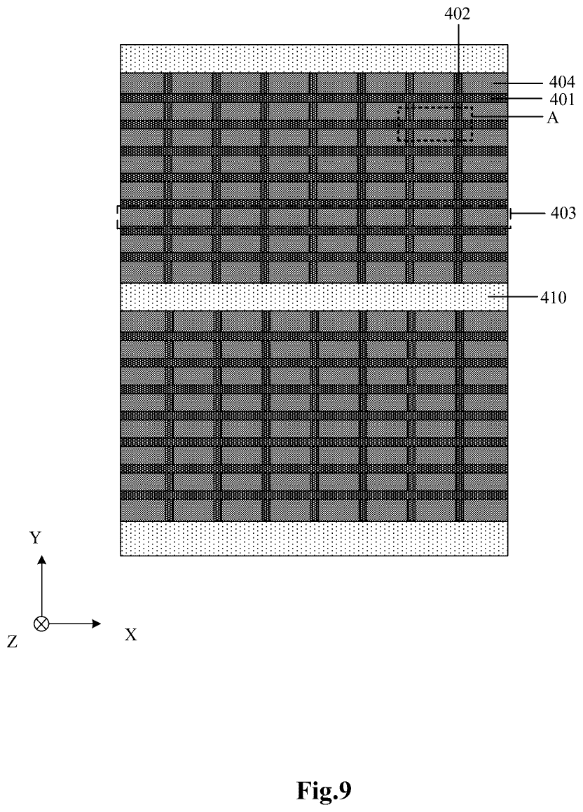

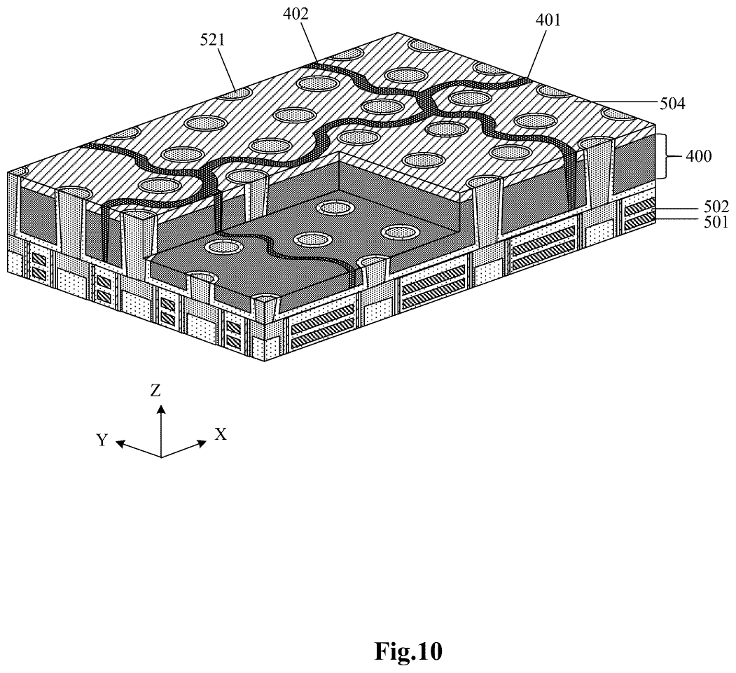

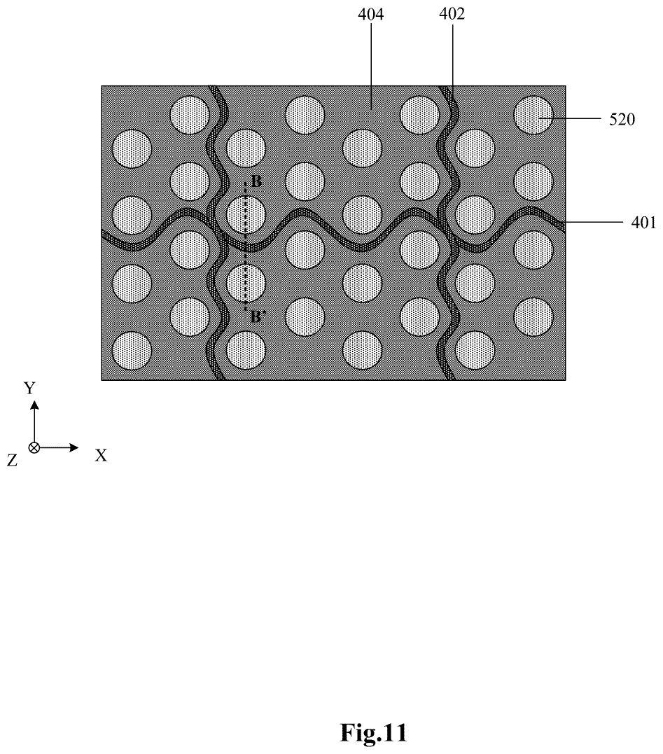

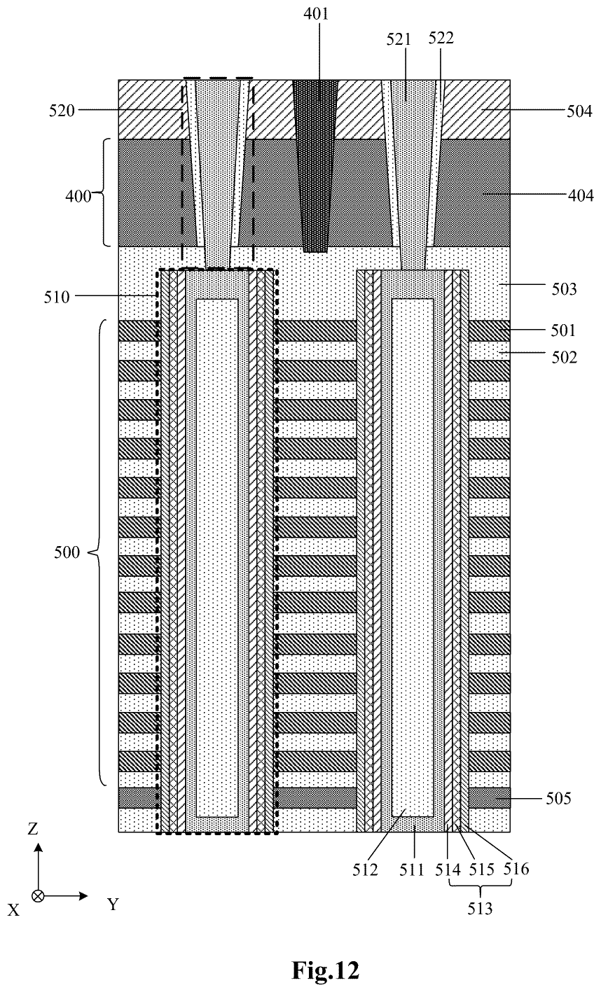

In some examples, FIG. 9 is a top view of a semiconductor device according to an example of the present disclosure, FIG. 10 is a perspective view of a partial structure in region A of FIG. 9, FIG. 11 is a top view of a partial structure in region A of FIG. 9, and FIG. 12 is a cross-sectional view along line BB′ in FIG. 11. With reference to FIG. 9 to FIG. 12, the semiconductor device according to the present disclosure comprises: a stack structure 500; the stack structure 500 comprises conductive layers 501 and insulating layers 502 that are stacked alternately along a first direction; a select gate layer 400 located on one of two opposite sides of the stack structure 500 along the first direction; a plurality of first select gate isolating structures 401 extending along a third direction and penetrating through the select gate layer 400 along the first direction; the first select gate isolating structure 401 divides the select gate layer 400 into a plurality of select gate rows 403 arranged along a second direction; and a plurality of second select gate isolating structures 402 extending along the second direction and penetrating through the select gate layer 400 along the first direction; the second select gate isolating structure 402 divides the select gate row 403 into a plurality of first select gates 404 arranged along the third direction.

In an example of the present disclosure, the second direction intersects with the third direction, and the second direction and the third direction are both perpendicular to the first direction. Here, taking the first direction being the Z direction, the second direction being the Y direction, and the third direction being the X direction as an example.

In an example of the present disclosure, the first select gate isolating structure 401 may divide the select gate layer 400 into a plurality of select gate rows 403 arranged along the second direction, and the second select gate isolating structure 402 may divide the select gate row 403 into a plurality of first select gates 404 arranged along the third direction, that is, the first select gate isolating structure 401 and the second select gate isolating structure 402 may divide the select gate layer 400 into a plurality of first select gates 404 arranged along the second direction and the third direction.

In some examples, the conductive layer 501 may comprise a conductive material, such as one or more of: a doped semiconductor material (doped silicon, doped germanium, etc.), a conductive metal nitride (titanium nitride, tantalum nitride, etc.), a metal material (tungsten, titanium, tantalum, aluminum, copper, etc.), and a metal semiconductor compound (tungsten silicide, cobalt silicide, titanium silicide, etc.); and the insulating layer 502 may be an insulating material, such as silicon oxide.

In some examples, the material of the select gate layer 400 may be different from the material of the conductive layer 501, for example, the material of the select gate layer 400 may comprise polysilicon.

In an example, the select gate layer 400 and the conductive layer 501 may be formed in different process steps. For example, an initial stack structure may be formed first, wherein the initial stack structure comprises sacrificial layers and insulating layers 502 stacked alternately along the first direction, and then the sacrificial layers may be replaced with conductive layers 501 to form a stack structure 500 in which conductive layers 501 and insulating layers 502 are stacked alternately in the first direction, and then the select gate layer 400 may be formed on one of two opposite sides of the stack structure 500 along the first direction.

In some examples, the first select gate isolating structure 401 and the second select gate isolating structure 402 may comprise a same material, for example, the first select gate isolating structure 401 and the second select gate isolating structure 402 may both comprise one or more of dielectric materials such as silicon oxide, silicon nitride, or silicon oxynitride. The first select gate isolating structure 401 and the second select gate isolating structure 402 may enable electrical isolation between two adjacent first select gates 404.

In some examples, with reference to FIG. 11 and FIG. 12, the semiconductor device further comprises: a plurality of first channel structures 510 extending along the first direction and penetrating through the stack structure 500; a second channel structure 520 extending along the first direction and penetrating through the first select gate 404; a channel layer 521 of one second channel structure 520 is connected to a channel layer 511 of one first channel structure 510; the first select gate isolating structure 401 is located between two adjacent second channel structures 520 in the second direction; and the second select gate isolating structure 402 is located between two adjacent second channel structures 520 in the third direction.

In some examples, the first channel structure 510 may be cylindrical and comprises a filling layer 512, a channel layer 511, and a functional layer 513 sequentially arranged along the radial direction. The filling layer 512 may comprise an insulating material, such as silicon oxide; the channel layer 511 may comprise a semiconductor material, such as polysilicon. The functional layer 513 may be a composite dielectric layer comprising a tunneling layer 514, a charge trapping layer 515, and a blocking layer 516, wherein the tunneling layer 514 may comprise silicon oxide, silicon oxynitride, or any combination thereof, the charge trapping layer 515 may comprise silicon nitride, silicon oxynitride, or any combination thereof, and the blocking layer 516 may comprise silicon oxide, silicon oxynitride, a high dielectric constant dielectric, or any combination thereof.

In some examples, the second channel structure 520 may be cylindrical and comprises a channel layer 521 and at least a dielectric layer 522 located between the select gate layer 400 and the channel layer 521. The channel layer 521 may comprise a semiconductor material, such as polysilicon, and the dielectric layer 522 may comprise silicon oxide, silicon oxynitride, a high dielectric constant dielectric, or any combination thereof.

In some examples, with reference to FIG. 10 and FIG. 12, the semiconductor device further comprises an isolation layer 504 located on one side that away from the stack structure 500, of two opposite sides of the select gate layer 400 along the first direction, and the second channel structure 520 may penetrate through the isolation layer 504 along the first direction. The isolation layer 504 may comprise one or more of dielectric materials such as silicon oxide, silicon nitride, or silicon oxynitride.

In some examples, referring to FIG. 10 and FIG. 11, the second channel structures 520 are in an array arrangement, as an example, for two adjacent rows of second channel structures 520 in the second direction, the second channel structures 520 in one row and the second channel structures 520 in the other row are staggered in the third direction, so the first select gate isolating structure 401 and the second select gate isolating structure 402 may be wavy, the overall extending direction of the first select gate isolating structure 401 is the third direction, and the first select gate isolating structure 401 is located between two adjacent second channel structures 520 in the second direction, the overall extending direction of the second select gate isolating structure 402 is the second direction, and the second select gate isolating structure 402 is located between two adjacent second channel structures 520 in the third direction.

In an example of the present disclosure, a radial size of the second channel structure 520 may be smaller than a radial size of the first channel structure 510, and a pitch between two adjacent second channel structures 520 may be greater than a pitch between two adjacent first channel structures 510, so that a larger disposing space may be provided for the first gate isolating structure 401 and the second gate isolating structure 402, and the first gate isolating structure 401 and the second gate isolating structure 402 may be disposed without sacrificing the memory density.

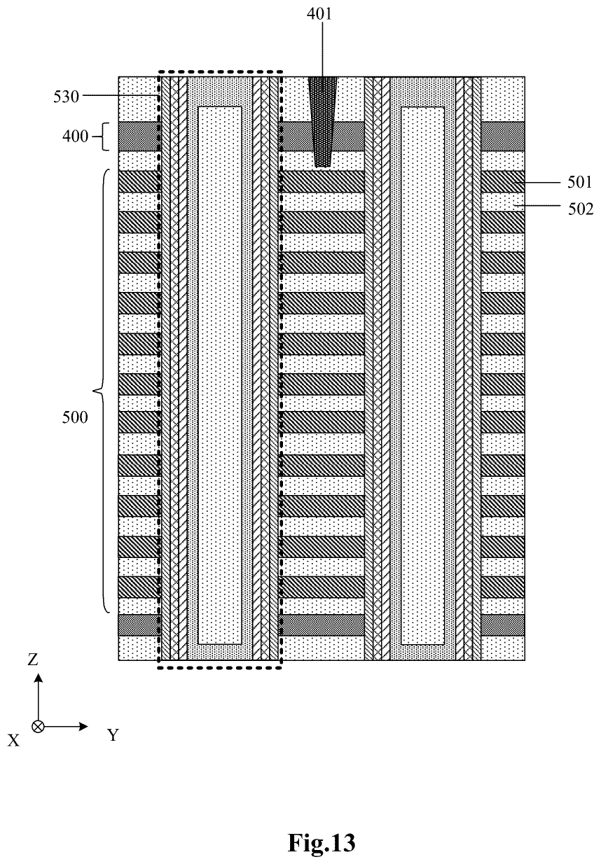

In some examples, referring to FIG. 13, the semiconductor device further comprises: a plurality of third channel structures 530 extending along the first direction and penetrating through the stack structure 500 and the select gate layer 400; wherein the first select gate isolating structure 401 is located between two adjacent third channel structures 530 in the second direction; and the second select gate isolating structure is located between two adjacent third channel structures 530 in the third direction.

In some examples, the material of the select gate layer 400 may be the same as the material of the conductive layer 501.

In an example, the select gate layer 400 and the conductive layer 501 may be formed in the same process steps. For example, an initial stack structure may be formed first, the initial stack structure comprises sacrificial layers and insulating layers 502 stacked alternately along the first direction, and then at least one sacrificial layer located at the top of the initial stack structure may be replaced with a select gate layer 400, and other sacrificial layers may be replaced with conductive layers 501, to form a stack structure 500 in which conductive layers 501 and insulating layers 502 are stacked alternately in the first direction.

In some examples, as shown in FIG. 9, the semiconductor device further comprises: a gate line slit structure 410 extending along the third direction and penetrating through the stack structure 500 and the select gate layer 400 along the first direction; wherein the gate line slit structure 410 divides the stack structure 500 and the select gate layer 400 into a plurality of memory blocks arranged along the second direction; and the memory block comprises a plurality of select gate rows 403.

In some examples, the gate line slit structure 410 may comprise one or more of dielectric materials such as silicon oxide, silicon nitride, silicon oxynitride, and semiconductor materials such as polysilicon.

It should be noted that FIG. 9 shows the first gate isolating structure 401 and the second gate isolating structure 402 in two memory blocks and the gate line slit structure 410 between the memory blocks in the semiconductor device, and taking the following as an example: select gate layer of each memory block being divided into eight select gate rows 403, and each select gate row 403 being divided into eight first select gates 404, but the present disclosure is not limited thereto, and the number of the respective structures is not limited in the present disclosure.

In some examples, as shown in FIG. 12, the memory block further comprises a second select gate 505, wherein the second select gate 505 is located on the other side of the two opposite sides of the stack structure 500 along the first direction. The second select gate 505 and the conductive layer 501 may comprise the same material.

In an example of the present disclosure, for a first channel structure 510 and a second channel structure 520 connected thereto, the plurality of conductive layers 501 surrounding the first channel structure 510 and the surrounded portion of the first channel structure 510 constitute a plurality of memory cells arranged along the first direction and connected in series, the second select gate 505 surrounding the bottom of the first channel structure 510 and the surrounded portion of the first channel structure 510 constitute a bottom select transistor, and the first select gate 404 surrounding the second channel structure 520 and the second channel structure 520 constitute a top select transistor, thereby a memory cell string comprising a top select transistor, memory cells, and a bottom select transistor connected in series may be formed.

In some examples, a same conductive layer 501 in a same memory block is continuous, that is, the same conductive layer 501 may serve as gates of all the memory cells in a same layer in the memory block.

In some examples, the conductive layer 501 constitutes a word line. In other examples, the conductive layer 501 is coupled to a word line, the word line may extend in the X direction to a lead-out region of the semiconductor device. In an example of the present disclosure, taking the conductive layer 501 being coupled to the word line as an example, the memory cell strings in a same memory block are all coupled to a same word line.

In an example of the present disclosure, the select gate layer 400 in a same memory block is divided into a plurality of first select gates 404 by the first select gate isolating structure 401 and the second select gate isolating structure 402, and one first select gate 404 may surround a plurality of second channel structures 520, that is, one first select gate 404 may be shared by top select transistors in the plurality of memory cell strings.

The above example takes the select gate layer being the top select gate layer, and the first select gate being the top select gate as an example, then the second select gate may be the bottom select gate. As shown in FIG. 12, the second select gate 505 is located on the other side of the two opposite sides of the stack structure 500 along the first direction, and in this case, the second select gates 505 in a same memory block may be continuous, and the second select gates 505 may be coupled to the bottom select line, then a plurality of memory cell strings in a same memory block are all coupled to a same bottom select line.

In some other examples, the first select gate may be a bottom select gate, the second select gate may be a top select gate, then the first select gate isolating structure and the second select gate isolating structure may divide the bottom select gate layer in the memory block into a plurality of first select gates, while the top select gate layer in the same memory block may be continuous. The following will continue to take the first select gate being the top select gate, and the second select gate being the bottom select gate as an example, to illustrate other structures in the semiconductor device.

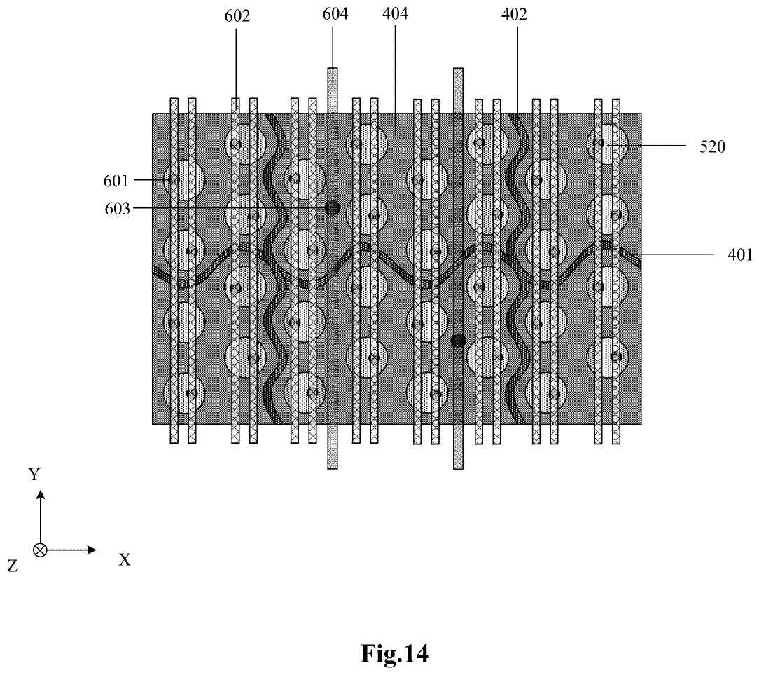

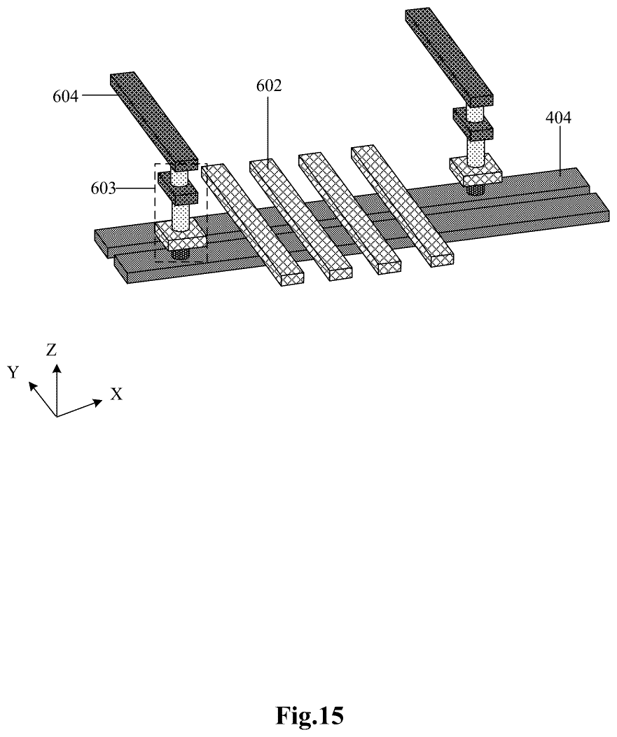

In some examples, with reference to FIG. 14 and FIG. 15, the semiconductor device further comprises: a plurality of bit lines 602 located on one side away from the stack structure 500, of two opposite sides of the select gate layer 400 along the first direction; wherein the bit lines 602 extend along the second direction and are arranged along the third direction.

In some examples, the bit line 602 is coupled to the second channel structure 520 through the bit line lead-out structure 601, so as to be coupled to the memory cell string.

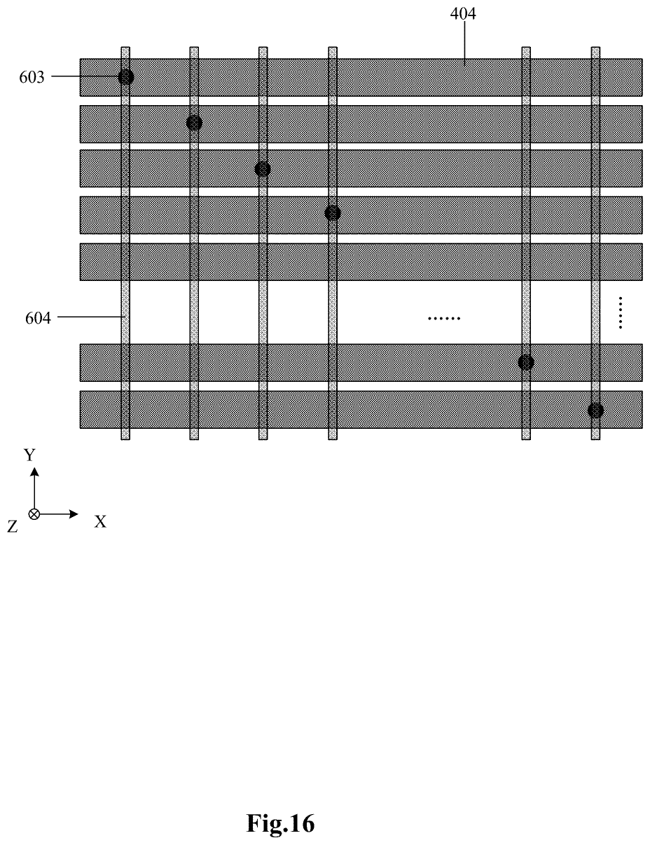

In some examples, with reference to FIG. 14, FIG. 15, and FIG. 16, the semiconductor device further comprises: a plurality of lead-out structures 603 located on one side away from the stack structure, of two opposite sides of the select gate layer 400 along the first direction; wherein one end of the two opposite ends of one lead-out structure 603 along the first direction is connected to one first select gate 404; at least one bit line 602 exists between two adjacent lead-out structures 603 in the third direction; and a conductive line 604 connected to the other end of the two opposite ends of the lead-out structure 603 along the first direction; wherein one conductive line 604 is connected to one lead-out structure 603; and the conductive lines 604 extend along the second direction and are arranged along the third direction.

In an example of the present disclosure, each first select gate 404 may be led out by a lead-out structure 603 extending along the first direction and a conductive line 604 extending along the second direction, an extending direction of the conductive line 604 may be the same as an extending direction of the bit line 602, and in the third direction, the bit lines 602 and the lead-out structures 603 may be alternately arranged, so that an lead-out structure 603 may be disposed using a gap between the bit lines 602.

In an example, as shown in FIG. 15, a height of the conductive line 604 in the first direction may be greater than a height of the bit line 602 in the first direction, that is, the conductive line 604 may be disposed in a higher level of metal layer relative to the bit line 602, thereby reducing a parasitic capacitance between the conductive line 604 and the bit line 602, and reducing crosstalk between the conductive line 604 and the bit line 602.

In an example, as shown in FIG. 16, for the plurality of first select gates 404 arranged along the second direction, each of the plurality of conductive lines 604 extending along the second direction and arranged along the third direction may be coupled to one first select gate 404 through one lead structure 603. It should be noted that the disposing position of the lead-out structure 603 shown in the figure is merely an example, and in other examples, the plurality of lead-out structures 603 may also be arranged in other manners, which is not limited in the present disclosure.

In an example of the present disclosure, when the semiconductor device according to the above example is used as the compute-in-memory chip, the input data may be converted into corresponding input voltages and input into the memory block through the plurality of first select gates in the memory block, so that the operation flexibility and efficiency can be improved. The following describes the operation scheme according to an example of the present disclosure in detail.

In an example of the present disclosure, a semiconductor device comprises a plurality of memory blocks and a peripheral circuit coupled to the plurality of memory blocks. As an example, the memory block may be coupled to the peripheral circuit through a conductive line coupled to the first select gate, a bottom select line coupled to the second select gate, and a word line and a bit line coupled to the conductive layer, and the peripheral circuit may be configured to apply corresponding voltages to the first select gate, the second select gate, the word line, and the bit line during an operation phase with the semiconductor device.

In some examples, the peripheral circuit is configured to: perform a programming operation on memory cells in the memory block based on a weight matrix, to write weights in the weight matrix to the memory cells, before the operation is performed with the semiconductor device.

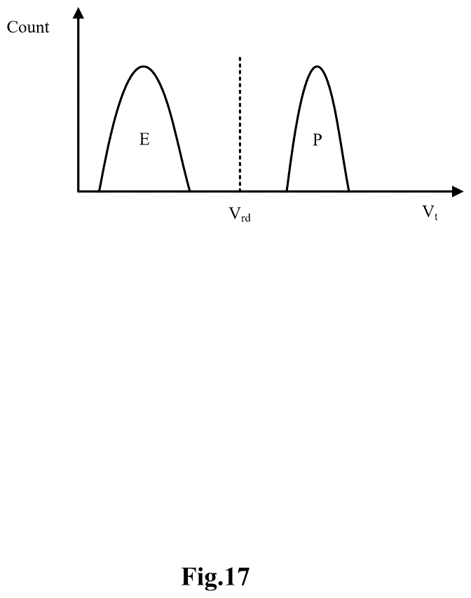

In some examples, FIG. 17 is a schematic diagram of a threshold voltage distribution of a memory cell. As shown in FIG. 17, the memory cell in the memory block is configured to store one bit of data, the plurality of memory cells in the memory block have a first memory state and a second memory state, a threshold voltage of the memory cell having the first memory state is less than a threshold voltage of the memory cell having the second memory state. The peripheral circuit may be configured to: perform a programming operation on the memory cells in the memory block and write the weights in the weight matrix to the memory cells according to a certain mapping rule before performing the operation. For a single-level cell, the first memory state may be an erased state E, and the second memory state may be a programmed state P, then the process of weight writing may comprise applying a corresponding program voltage to adjust the threshold voltages of some of the memory cells in the memory block to be within a range of the threshold voltage distribution corresponding to the second memory state.

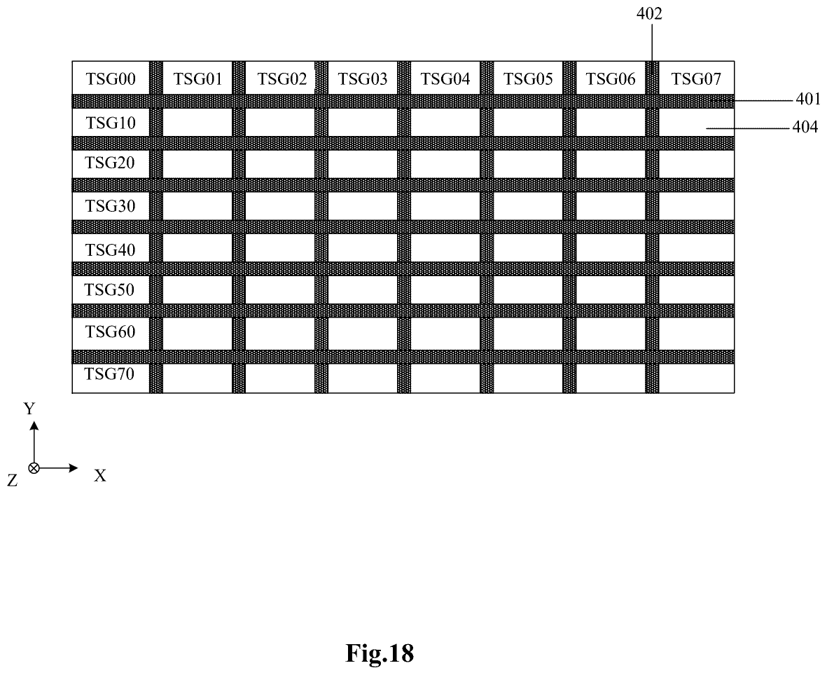

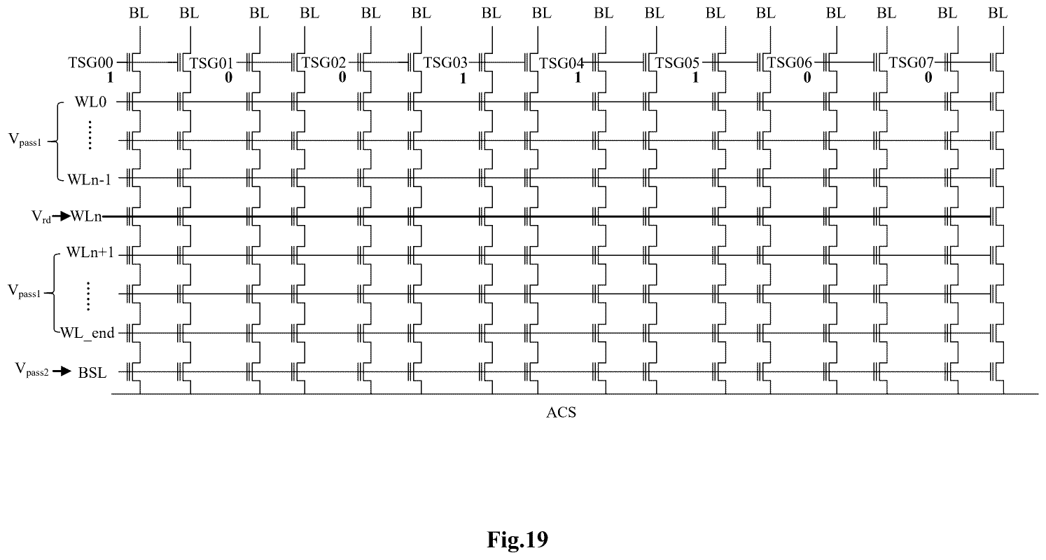

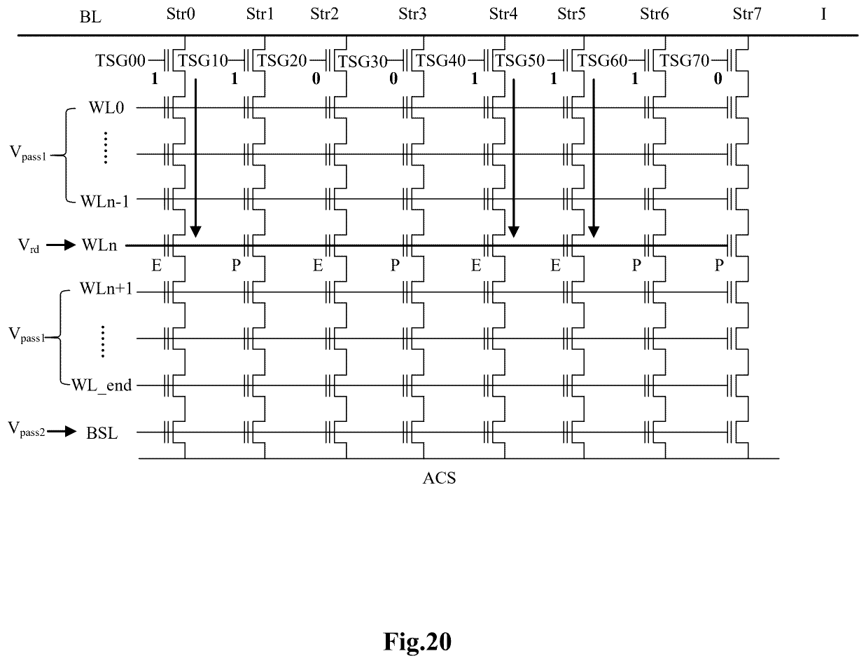

In some examples, FIG. 18 is a schematic diagram of an arrangement of first select gates in a memory block according to an example of the present disclosure, FIG. 19 is an equivalent circuit diagram of a plurality of memory cell strings comprising one select gate row, and FIG. 20 is an equivalent circuit diagram of a plurality of memory cell strings coupled to one bit line. Here, for ease of description, FIG. 19 takes each first select gate in a same select gate row controlling top select transistors in two memory cell strings as an example, and FIG. 20 takes one bit line being coupled to eight memory cell strings in the memory block as an example, but the present disclosure is not limited thereto.

In some examples, the peripheral circuit is further configured to: apply a same voltage to a plurality of first select gates in a same select gate row in the memory block, during programming phase on the memory cells in the memory block.

In some examples, with reference to FIG. 18 and FIG. 19, taking the plurality of first select gates TSG00 to TSG07 located in the same select gate row as an example, during programming phase on the memory cells in the memory block, a same voltage may be applied to the plurality of first select gates TSG00 to TSG07, so that the top select transistors in the plurality of memory cell strings comprising the plurality of first select gates in the select gate row are turned on or turned off at the same time.

In some examples, the peripheral circuit is configured to: apply corresponding input voltages to a plurality of first select gates in the memory block based on input data, during an operation phase with the semiconductor device.

Here, the input data may be an input vector or an input matrix comprising a plurality of elements, the peripheral circuit may be configured to: convert each element of the input data into a corresponding input voltage, and apply the input voltages to the plurality of first select gates in the memory block, and the number of elements input into the memory block may be the same as the number of the first select gates in the memory block.

In some examples, with reference to FIG. 18, FIG. 19, and FIG. 20, taking a memory block comprising 64 first select gates 404 as an example, a plurality of input voltages corresponding to a column of elements [11001110] of the input data may be input to the eight first select gates respectively from TSG00 to TSG70, and for a plurality of first select gates TSG00 to TSG07 in the same select gate row, the input elements may belong to eight columns of elements respectively. Therefore, 64 input voltages corresponding to eight columns of elements can be applied to 64 first select gates respectively. An input voltage corresponding to “1” may cause the top select transistor comprising the first select gate to be turned on, and an input voltage corresponding to “0” may cause the top select transistor comprising the first select gate to be turned off.

In an example of the present disclosure, a memory block may comprise X select gate rows, each select gate row may comprise Y first select gates, thus the memory block may comprise X*Y first select gates, and the peripheral circuit may be configured to apply corresponding input voltages to X*Y first select gates at the same time based on the input data, and thus the X*Y elements may be input at a time. Compared with an operation scheme in which only one element of the input data can be input at a time, the operation scheme implemented with the semiconductor device according to the present disclosure can greatly improve the input parallelism, so that the operation flexibility and the operation efficiency can be significantly improved, which is beneficial for implementing more complex operation scheme with the semiconductor device.

In some examples, the peripheral circuit is further configured to: apply a read voltage to a target word line coupled to the memory block during an operation phase with the semiconductor device; and apply a first turn-on voltage to a non-target word line coupled to the memory block.

In some examples, with reference to FIG. 17, FIG. 18 and FIG. 19, the read voltage V_{rd} applied to the target word line WLn may be greater than a threshold voltage of the memory cell in the first memory state (erased state E) and less than a threshold voltage of the memory cell in the second memory state (programmed state P).

In some examples, with reference to FIG. 18 and FIG. 19, during the operation phase with the semiconductor device, the peripheral circuit is further configured to: apply a first turn-on voltage Vₚₐₛₛ₁ to a non-target word line coupled to the memory block to turn on the memory cells coupled to the non-target word line; and apply a second turn-on voltage Vₚₐₛₛ₂ to a bottom select line BSL coupled to the memory block to turn on bottom select transistors coupled to the bottom select line BSL. Here, the non-target word line may comprise WL0˜WLn-1 and WLn+1˜WL_end, WL0 represents the first word line coupled to the memory block, and WL_end represents the last word line coupled to the memory block.

In an example of the present disclosure, during the operation phase with the semiconductor device, the peripheral circuit is configured to: obtain an operation result of the input data and the weights stored in the memory cells coupled to the target word lines based on currents on a plurality of bit lines coupled to the memory block. As an example, the current on one bit line coupled to the memory block is a sum of the output currents of the plurality of memory cell strings coupled to the bit line in the memory block; the output current of the memory cell string may be greater than or equal to a preset current, in the circumstance that the input voltage applied to the first select gate makes the select transistor comprising the first select gate being in the turn-on state, and the threshold voltage of the memory cell coupled to the target word line in the memory cell string less than the read voltage.

Here, the magnitude of the preset current may be set based on the magnitude of the read voltage V_{rd} applied to the target word line WLn, the magnitude of the target voltage on the sensing node coupled to the bit line, and the threshold voltage of the memory cell in the first memory state, in addition, in the circumstance that the input voltage applied to the first select gate makes the select transistor comprising the first select gate being in the turn-on state, and the threshold voltage of the memory cell coupled to the target word line in the memory cell string less than the read voltage, the output current of the memory cell string is greater than or equal to the preset current, and the output currents generated by the memory cell strings coupled to the same bit line that are greater than or equal to the preset current are substantially equal; while in at least one of the circumstance that the input voltage makes the select transistor comprising the first select gate being in the turn-off state or the threshold voltage of the memory cell coupled to the target word line in the memory cell string is greater than the read voltage, the memory cell string may also generate a current, but the current generated by the memory cell string should be far less than the preset current. Therefore, an operation result may be obtained according to a multiple relation between the current on the bit line and the output current greater than or equal to the preset current.

In an example, referring to FIG. 20, the current I on the bit line BL is the sum of the output currents of the eight memory cell strings coupled to the bit line BL, wherein the select transistor comprising the first select gate TSG00, the select transistor comprising the first select gate TSG40, and the select transistor comprising the first select gate TSG50 are in the turn-on state, and the memory cells coupled to the target word line WLn in the memory cell strings Str0, Str4, and Str5 have the first memory state (erased state E), their threshold voltages are less than the read voltage V_{rd}, thus the memory cell strings Str0, Str4, and Str5 are turned on and may generate a current greater than or equal to the preset current, the current I on the bit line BL and the sum of the output currents of the memory cell strings Str0, Str4 and Str5 are substantially equal, and the current I is approximately three times the current generated by any one of the memory cell strings Str0, Str4 and Str5. If the weight value stored in a memory cell in the first memory state is equivalent to “1”, and the weight value stored in a memory cell in the second memory state is equivalent to “0”, the operations performed by the eight memory cell strings coupled to the bit line BL may be equivalent to: 1*1+1*0+0*1+0*0+1*1+1*1+1*0+0*0=3.

In an example of the present disclosure, the operations performed by the memory cell strings coupled to other bit lines are similar to the operations performed by the memory cell strings coupled to the bit line BL in the above example. Since the plurality of input voltages corresponding to the plurality of columns of elements may be simultaneously input from the plurality of first select gates in the memory block at a time, the operations corresponding to the currents on the plurality of bit lines BL respectively may be performed in parallel, thereby the operation efficiency of the semiconductor device may be improved.

The operation scheme according to the above example takes the first select gate being the top select gate, and the second select gate being the bottom select gate as an example. In other examples, the first select gate may be a bottom select gate, the second select gate may be a top select gate, then one memory block may comprise a plurality of bottom select gates and one continuous top select gate, the top select gate may be coupled to the top select line, and the peripheral circuit may be configured to: apply corresponding input voltages to the plurality of bottom select gates in the memory block simultaneously based on the input data during the operation phase with the semiconductor device, that is, input may be done through the bottom select gate, and in this case, the peripheral circuit may be further configured to: apply a turn-on voltage to the top select line, to turn on the top select transistors in the memory block coupled to the top select line.

In some examples, referring back to FIG. 8, the semiconductor device comprises a plurality of memory banks, the memory bank comprises a plurality of memory blocks arranged along the second direction, one bit line is coupled to all the plurality of memory blocks arranged along the second direction, and the peripheral circuit is further configured to: apply corresponding input voltages to a plurality of first select gates in at least two memory blocks in the memory banks simultaneously based on input data during the operation phase with the semiconductor device.

In an example of the present disclosure, in addition to the input parallelism of a single memory block may be increased, a plurality of memory blocks in a same memory bank may also be used to perform operations in parallel, and a current on a bit line may be an accumulation after multiplications are performed on memory cell strings coupled to the bit line in all memory blocks participating in operations. Therefore, at least one of the number of elements of the input data or the number of weights of the weight matrix may be increased, thereby further improving the computing power of the semiconductor device.

In some examples, the plurality of memory blocks and the peripheral circuit in the semiconductor device are stacked along the first direction.

In some examples, the semiconductor device comprises a first semiconductor structure and a second semiconductor structure, the plurality of memory blocks are located in the first semiconductor structure, the peripheral circuit is located in the second semiconductor structure, and the first semiconductor structure and the second semiconductor structure are stacked along the first direction.

In some examples, the semiconductor device comprises a first semiconductor structure, a bonding layer, and a second semiconductor structure stacked along a thickness direction of the semiconductor device; the plurality of memory blocks are located in the first semiconductor structure, the peripheral circuit is located in the second semiconductor structure, and the peripheral circuit is coupled to the plurality of memory blocks through a bonding structure in the bonding layer.

In some examples, the first semiconductor structure and the second semiconductor structure of the semiconductor device may be formed by bonding two wafers, for example, the first semiconductor structure may be formed on one wafer, the second semiconductor structure may be formed on another wafer, and then the two wafers may be bonded, the first semiconductor structure and the second semiconductor structure are stacked along the first direction. In other examples, the first semiconductor structure and the second semiconductor structure of the semiconductor device may also be formed on a same wafer, but the first semiconductor structure and the second semiconductor structure are stacked along the first direction, and the architecture in which the first semiconductor structure and the second semiconductor structure are stacked along the thickness direction of the semiconductor device can further save the area of the semiconductor device.

In an example of the present disclosure, the semiconductor device comprises a select gate layer located on one of two opposite sides of the stack structure along the first direction, the select gate layer may be divided into a plurality of first select gates by a first select gate isolating structure extending along the third direction and a second select gate isolating structure extending along the second direction, and during the operation phase with the semiconductor device, the peripheral circuit may be configured to apply corresponding input voltages to the plurality of first select gates in the memory block based on the input data. As a result, the input parallelism can be improved, which can significantly improve the flexibility and efficiency of the operation, and facilitate the implementation of more complex operation schemes with the semiconductor device.

Based on a concept similar to that of the above semiconductor device, the present disclosure further provides a system, comprising: at least one semiconductor device according to any one of the above implementations; and a controller coupled to the at least one semiconductor device and configured to transmit input data to the semiconductor device and receive an operation result of the semiconductor device.

In some examples, the operation result of the semiconductor device may be an operation result obtained based on the current on the bit line in the above example.

In some other examples, the peripheral circuit in the semiconductor device may be further configured to: perform a logic operation on the operation result obtained based on the current on the bit line, and the operation result of the semiconductor device may be an operation result obtained by performing a logic operation again on the operation result obtained based on the current on the bit line in the above example.

In some examples, reference may be made to the description of FIG. 1 to FIG. 6 for the specific composition and function implementation of the system, which is not repeated here for brevity.

Based on a concept similar to that of the above semiconductor device, the present disclosure further provides an operating method of a semiconductor device. The semiconductor device comprises a plurality of memory blocks; the memory block comprises a plurality of select gate rows arranged along a second direction; the select gate row comprises a plurality of first select gates arranged along a third direction; the second direction intersects with the third direction; and the operating method of the semiconductor device comprises: applying corresponding input voltages to a plurality of first select gates in the memory block simultaneously based on input data during an operation phase with the semiconductor device.

In an example of the present disclosure, by applying corresponding input voltages to a plurality of first select gates in the memory block simultaneously based on input data, the input parallelism may be improved, thereby improving the efficiency of performing the operation with the semiconductor device.

In some examples, the semiconductor device comprises a plurality of memory banks; the memory bank comprises a plurality of memory blocks arranged along the second direction; and the operating method of the semiconductor device further comprises: applying corresponding input voltages to a plurality of first select gates in at least two memory blocks in the memory banks simultaneously based on input data during the operation phase with the semiconductor device.

In an example of the present disclosure, the plurality of memory blocks in the memory bank may be used to perform an operation simultaneously, thereby further improving the efficiency of performing the operation with the semiconductor device.

In some examples, the operating method of the semiconductor device further comprises: performing a programming operation on memory cells in the memory block based on a weight matrix to write weights in the weight matrix to the memory cells, before the operation is performed with the semiconductor device.

In some examples, the operating method of the semiconductor device further comprises: applying a same voltage to a plurality of first select gates in a same select gate row in the memory block during a programming phase on the memory cells in the memory block.

In some examples, the operating method of the semiconductor device further comprises: applying a read voltage to a target word lines coupled to the memory block during the operation phase with the semiconductor device; applying a first turn-on voltage to a non-target word line coupled to the memory block; and obtaining an operation result of the input data and the weights stored in the memory cells coupled to the target word line based on currents on a plurality of bit lines coupled to the memory block.

In some examples, each memory block comprises a plurality of memory cell strings, one bit line is coupled to the plurality of memory cell strings in the memory block; a current on the one bit line coupled to the memory block is a sum of output currents of the plurality of memory cell strings coupled to the bit line in the memory block; in the circumstance that the input voltage applied to the first select gate makes a select transistor comprising the first select gate being in a turn-on state, and a threshold voltage of a memory cell coupled to the target word line in the memory cell string is less than the read voltage, an output current of the memory cell string is greater than or equal to a preset current.

In some examples, the memory block further comprises a second select gate; and the operating method of the semiconductor device further comprises: applying a second turn-on voltage to the second select gate in the memory block during the operation phase with the semiconductor device.

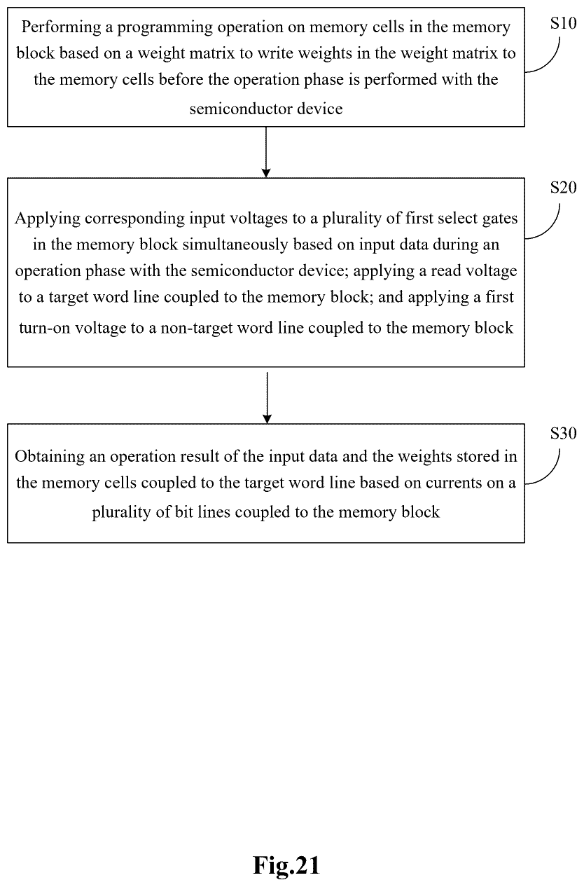

In an example, FIG. 21 is a schematic flowchart of an operating method of a semiconductor device according to an example of the present disclosure, referring to FIG. 21, the operating method of the semiconductor device comprises the following operations:
Operation S10: performing a programming operation on memory cells in the memory block based on a weight matrix to write weights in the weight matrix to the memory cells before the operation phase is performed with the semiconductor device;
Operation S20: applying corresponding input voltages to a plurality of first select gates in the memory block simultaneously based on input data during an operation phase with the semiconductor device; applying a read voltage to a target word line coupled to the memory block; and applying a first turn-on voltage to a non-target word line coupled to the memory block;
Operation S30: obtaining an operation result of the input data and the weights stored in the memory cells coupled to the target word line based on currents on a plurality of bit lines coupled to the memory block.

It should be noted that the flow of the operating method of the semiconductor device shown in FIG. 21 is merely an example, and the flow of the operating method is not limited in the present disclosure.

In an example of the present disclosure, the memory block in the semiconductor device comprises a plurality of select gate rows, the select gate row comprises a plurality of first select gates, the plurality of first select gates in the memory block may be applied with corresponding input voltages based on the input data during the operation phase with the semiconductor device, therefore the input parallelism can be improved, which can significantly improve the flexibility and efficiency of the operation, and facilitate the implementation of more complex operation schemes.

The features disclosed in the several device examples according to the present disclosure may be arbitrarily combined without conflict, to obtain a new device example.

The methods disclosed in the several method examples according to the present disclosure may be arbitrarily combined without conflict, to obtain a new method example.

The above descriptions are only specific implementations of the present disclosure, but the protection scope of the present disclosure is not limited thereto, and changes or replacements that may be easily conceived by any person skilled in the art within the technical scope of the present disclosure should be covered within the protection scope of the present disclosure.

What is claimed is:

1. A semiconductor device, comprising:
a stack structure comprising conductive layers and insulating layers stacked alternately along a first direction;
a select gate layer located on one of two opposite sides of the stack structure along the first direction;
a plurality of first select gate isolating structures penetrating through the select gate layer along the first direction, wherein a first select gate isolating structure of the plurality of first select gate isolating structures divides the select gate layer into a plurality of select gate rows arranged along a second direction, the plurality of first select gate isolating structure extending along a third direction, the second direction intersects with the third direction, and the second direction and the third direction are both perpendicular to the first direction; and
a plurality of second select gate isolating structures extending along the second direction and penetrating through the select gate layer along the first direction, wherein a second select gate isolating structure of the plurality of second select isolating structures divides one or more of the plurality of select gate rows into a plurality of first select gates arranged along the third direction.

2. The semiconductor device of claim 1, further comprising:
a plurality of first channel structures extending along the first direction and penetrating through the stack structure; and
a plurality of second channel structures extending along the first direction and penetrating through the first select gate,
wherein a channel layer of the plurality of second channel structures is connected to a channel layer of a first channel structure of the plurality of first channel structures, the first select gate isolating structure is located between two first adjacent ones of the plurality of second channel structures in the second direction, the second select gate isolating structure is located between two second adjacent ones of the plurality of second channel structures in the third direction, and a material of the select gate layer is different from a material of the conductive layers of the stack structure.

3. The semiconductor device of claim 1, further comprising:
a plurality of third channel structures extending along the first direction and penetrating through the stack structure and the select gate layer,
wherein the first select gate isolating structure is located between two first adjacent ones of the plurality of third channel structures in the second direction, and wherein the second select gate isolating structure is located between two second adjacent ones of the plurality of third channel structures in the third direction, and wherein a material of the select gate layer is the same as a material of the conductive layers of the stack structure.

4. The semiconductor device of claim 1, further comprising:
a gate line slit structure extending along the third direction and penetrating through the stack structure and the select gate layer along the first direction, wherein the gate line slit structure divides the stack structure and the select gate layer into a plurality of memory blocks arranged along the second direction, and wherein a memory block of the plurality of memory blocks comprises corresponding select gate rows of the plurality of select gate rows.

5. The semiconductor device of claim 4, further comprising:
a plurality of bit lines located on a first side away from the stack structure of two opposite sides of the select gate layer along the first direction, wherein the plurality of bit lines extend along the second direction and are arranged along the third direction, and a bit line of the plurality of bit lines is coupled to corresponding memory blocks of the plurality of memory blocks arranged along the second direction; and
a plurality of lead-out structures located on the first side away from the stack structure of the two opposite sides of the select gate layer along the first direction, wherein a first end of two opposite ends of a lead-out structure of the plurality of lead-out structures along the first direction is connected to a corresponding first select gate of the plurality of first select gates, and wherein at least one of the plurality of bit lines exists between two adjacent ones of the plurality of lead-out structures in the third direction.

6. The semiconductor device of claim 5, further comprising:
a conductive wire connected to a second end of the two opposite ends of the lead-out structure along the first direction, wherein one conductive wire is connected to one of the plurality of lead-out structures, and wherein a plurality of conductive wires connected to the plurality of lead-out structures extend along the second direction and are arranged along the third direction.

7. The semiconductor device of claim 5, further comprising:
a peripheral circuit coupled to the plurality of memory blocks and configured to:
apply input voltages to first select gates in the memory block simultaneously based on input data during an operation phase with the semiconductor device.

8. The semiconductor device of claim 7, further comprising a plurality of memory banks, wherein a memory bank of the plurality of memory banks comprises memory blocks arranged along the second direction, and a corresponding bit line of the plurality of bit lines is coupled to the memory blocks arranged along the second direction in the memory bank, and
wherein the peripheral circuit is further configured to:
apply corresponding input voltages to first select gates in at least two ones of the memory blocks in the memory bank simultaneously based on the input data during the operation phase with the semiconductor device.

9. The semiconductor device of claim 7, wherein the peripheral circuit is further configured to:
perform a programming operation on memory cells in the memory block based on a weight matrix to write weights in the weight matrix to the memory cells before the operation phase is performed with the semiconductor device.

10. The semiconductor device of claim 9, wherein the peripheral circuit is further configured to:
apply a same voltage to corresponding first select gates in a same select gate row in the memory block during a programming phase on the memory cells in the memory block.

11. The semiconductor device of claim 9, wherein the peripheral circuit is further configured to:
apply a read voltage to a target word line coupled to the memory block during the operation phase with the semiconductor device;
apply a first turn-on voltage to a non-target word line coupled to the memory block; and
obtain an operation result of the input data and the weights stored in the memory cells coupled to the target word line based on currents on corresponding bit lines coupled to the memory block.

12. The semiconductor device of claim 11, wherein the memory block comprises a plurality of memory cell strings, a corresponding bit line of the corresponding bit lines is coupled to the plurality of memory cell strings in the memory block, and wherein a current on the corresponding bit line coupled to the memory block is a sum of output currents of the plurality of memory cell strings coupled to the bit line in the memory block; and
in a circumstance that the input voltage applied to the first select gate makes a select transistor comprising the first select gate being in a turn-on state and that a threshold voltage of a memory cell coupled to the target word line in a memory cell string is less than the read voltage, an output current of the memory cell string is greater than or equal to a preset current.

13. The semiconductor device of claim 7, wherein the memory block further comprises a second select gate, and wherein the second select gate is located on the other side of the two opposite sides of the stack structure along the first direction, and
wherein the peripheral circuit is further configured to:
apply a second turn-on voltage to the second select gate in the memory block during the operation phase with the semiconductor device.

14. The semiconductor device of claim 13, wherein the first select gate is one of a top select gate and a bottom select gate, and the second select gate is the other one of the top select gate and the bottom select gate.

15. The semiconductor device of claim 7, wherein the peripheral circuit comprises:
an analog-to-digital conversion circuit, a digital-to-analog conversion circuit, a voltage generator, a column decoder, and a control logic,
wherein the analog-to-digital conversion circuit is coupled to the column decoder and the control logic, and the digital-to-analog conversion circuit is coupled to the voltage generator and the control logic.

16. The semiconductor device of claim 7, wherein the plurality of memory blocks and the peripheral circuit are stacked along the first direction.

17. The semiconductor device of claim 1, wherein the semiconductor device comprises a three-dimensional NAND type memory.

18. A system, comprising:
at least one semiconductor device each comprising:
a stack structure comprising conductive layers and insulating layers stacked alternately along a first direction;
a select gate layer located on one of two opposite sides of the stack structure along the first direction;
a plurality of first select gate isolating structures penetrating through the select gate layer along the first direction, wherein a first select gate isolating structure of the plurality of first select gate isolating structures divides the select gate layer into a plurality of select gate rows arranged along a second direction, wherein the plurality of first select gate isolating structures extend along a third direction, wherein the second direction intersects with the third direction, and the second direction and the third direction are both perpendicular to the first direction; and
a plurality of second select gate isolating structures extending along the second direction and penetrating through the select gate layer along the first direction, wherein a second select gate isolating structure of the plurality of second select gate isolating structures divides the select gate row into a plurality of first select gates arranged along the third direction; and
a controller coupled to the at least one semiconductor device and configured to transmit input data to the at least one semiconductor device and receive an operation result of the at least one semiconductor device.

19. An operating method of a semiconductor device, comprising:
applying corresponding input voltages to a plurality of first select gates in a memory block of the semiconductor device simultaneously based on input data during an operation phase with the semiconductor device,
wherein the semiconductor device comprises: a stack structure comprising conductive layers and insulating layers stacked alternately along a first direction, and a select gate layer located on one of two opposite sides of the stack structure along the first direction,
wherein the semiconductor device comprises a plurality of memory blocks including the memory block, the memory block comprises a plurality of select gate rows arranged along a second direction, and a select gate row of the plurality of select gate rows comprises a plurality of first select gates arranged along a third direction,
wherein the second direction intersects with the third direction, and the second direction and the third direction are both perpendicular to the first direction.

20. The operating method of claim 19, wherein the semiconductor device comprises a plurality of memory banks, and a memory bank of the plurality of memory banks comprises corresponding memory blocks arranged along the second direction, and
wherein the operating method further comprises:
applying corresponding input voltages to corresponding first select gates in at least two of the corresponding memory blocks in the memory bank simultaneously based on the input data during the operation phase with the semiconductor device.
